(19) United States
(12) Patent Application Publication
(10) Pub. No.: US 2026/0068443 A1
(43) Pub. Date: Mar. 5, 2026

(54) DISPLAY PANEL, MANUFACTURING METHOD OF DISPLAY PANEL AND DISPLAY DEVICE

(71) Applicant: Guangzhou China Star Optoelectronics Semiconductor Display Technology Co., LTd., Guangzhou (CN)

(72) Inventor: Jia TANG, Guangzhou (CN)

(73) Assignee: Guangzhou China Star Optoelectronics Semiconductor Display Technology Co., LTd., Guangzhou (CN)

(21) Appl. No.: 18/964,423

(22) Filed: Nov. 30, 2024

(30) Foreign Application Priority Data
Sep. 4, 2024 (CN) 202411237136.4

(51) Int. Cl. H10K 59/123; G02F 1/1368; H10K 59/12; H10K 59/121; H10K 59/131

(52) U.S. Cl. CPC H10K 59/123; G02F 1/1368; H10K 59/1201; H10K 59/1213; H10K 59/131

(57) ABSTRACT

A display panel, a manufacturing method thereof, and a display device are provided. The display panel includes a substrate, a first conductive layer, an active layer and a second conductive layer. The first conductive layer is disposed on the substrate, and the first conductive layer includes a data line. The active layer is disposed on a side of the first conductive layer away from the substrate, and the active layer includes a channel portion, and a first contacting portion and a second contacting portion. The second conductive layer is disposed on a side of the active layer away from the first conductive layer. The second conductive layer includes a first electrode and a second electrode, the first electrode connects the first contacting portion and the data line, the second electrode is connected to the second contacting portion, and the second electrode includes a pixel electrode or an anode.

### CROSS-REFERENCE TO RELATED APPLICATION

This application claims priority to and the benefit of Chinese Patent Application No. 202411237136.4, filed on Sep. 4, 2024, the disclosure of which is incorporated herein by reference in its entirety.

### TECHNICAL FIELD

The present disclosure relates to the field of display technology, and in particular, to a display panel, a manufacturing method of display panel and a display device.

### BACKGROUND

Thin film transistor (TFT) array substrate is an important part of the display device, it can be formed on a glass substrate or a plastic substrate, and it is generally used as a switching device and a driving device in devices such as liquid crystal display (LCD) and in organic light emitting display (OLED).

A large number of masks are required in the manufacturing process of the current array substrate, the mask cost is high, therefore, the greater the number of masks, the higher the cost of the manufacturing process of the thin film transistor array substrate, and the process time and complexity are increased.

### SUMMARY

Embodiments of the present disclosure provide a display panel, a manufacturing method of a display panel, and a display device, which can reduce the number of masks in the manufacturing process of a display panel and reduce production cost.

An embodiment of the present disclosure provides a display panel including: a substrate; a first conductive layer disposed on the substrate, wherein the first conductive layer includes a data line; an active layer disposed on a side of the first conductive layer away from the substrate, wherein the active layer includes a channel portion, and a first contacting portion and a second contacting portion connected to two opposite sides of the channel portion; and a second conductive layer disposed on a side of the active layer away from the first conductive layer; wherein the second conductive layer includes a first electrode and a second electrode, the first electrode connects the first contacting portion and the data line, the second electrode is connected to the second contacting portion, and the second electrode includes a pixel electrode or an anode.

According to the above object of the present disclosure, an embodiment of the present disclosure further provides a manufacturing method of a display panel including: forming a first conductive layer on a substrate, wherein a data line is formed in the first conductive layer; forming an active layer on a side of the first conductive layer away from the substrate, wherein a channel portion, and a first contacting portion and a second contacting portion connected to two opposite sides of the channel portion are formed in the active layer; and forming a second conductive layer on a side of the active layer away from the first conductive layer, wherein a first electrode and a second electrode are formed in the second conductive layer, the first electrode connects the first contacting portion and the data line, the second electrode is connected to the second contacting portion, and the second electrode includes a pixel electrode or an anode.

According to the above object of the present disclosure, an embodiment of the present disclosure further provides a display device, the display device includes the display device described above, or a display device manufactured by the manufacturing method of a display panel.

Other features and advantages of the present disclosure will be described in detail in the following detailed description.

### BRIEF DESCRIPTION OF THE DRAWINGS

In order to explain the technical solutions in the embodiments of the present disclosure more clearly, the accompanying drawings required in the description of the embodiments will be briefly introduced below. It is apparent that the accompanying drawings in the following description are only some embodiments of the present disclosure. For those skilled in the art, other accompanying drawings can be obtained based on these drawings without making creative efforts.

For a more complete understanding of the present disclosure and its beneficial effects, the following description will be made in combination with the accompanying drawings, and the same reference numerals refer to the same parts in the following description.

FIG. 1 is a schematic diagram of a structure of a display panel;

FIG. 2 is a schematic diagram of another structure of a display panel;

FIG. 3 is a schematic diagram of a structure of a display panel according to some embodiments of the present disclosure;

FIG. 4 is a schematic diagram of another structure of a display panel according to some embodiments of the present disclosure;

FIG. 5 is a flow diagram of a manufacturing method of a display panel according to some embodiments of the present disclosure;

FIG. 6 to FIG. 9 are schematic diagrams of structures in a manufacturing process of a display panel according to some embodiments of the present disclosure.

Explanation of reference numerals:
10. Substrate; 101. Display area; 102. Non-display area;
20. First conductive layer; 21. Data line; 22. Light-shielding portion; 23. First signal line;
30. Active layer; 31. Channel portion; 32. First contacting portion; 33. Second contacting portion;
40. Second conductive layer; 41. First electrode; 42. Second electrode; 44. Transfer line;
51. Buffer layer; 52. First insulating layer; 53. Organic insulating layer; 54. Second insulating layer; 55. First gate insulating portion; 56. Second gate insulating portion; 57 Common electrode layer;
60. Third conductive layer; 61. Gate; 62. Second signal line;
710. First middle hole; 71. First opening; 711. First sub-opening; 712. Second sub-opening; 720. Second middle hole; 72. Second opening; 721. Third sub-opening; 722. Fourth sub-opening; 730. Third middle hole; 73. Third opening;
81. Pixel defining layer; 82. Light-emitting functional layer; 83. Cathode layer.

### DETAILED DESCRIPTION

The technical solutions in the embodiments of the present disclosure will be clearly and completely described below with reference to the accompanying drawings in the embodiments of the present disclosure. It is apparent that the embodiments described are only part of the embodiments of the present disclosure, but not all the embodiments of the present disclosure. Based on the embodiments in the present disclosure, all other embodiments obtained by those skilled in the art without making creative efforts fall within the scope of protection of the present disclosure.

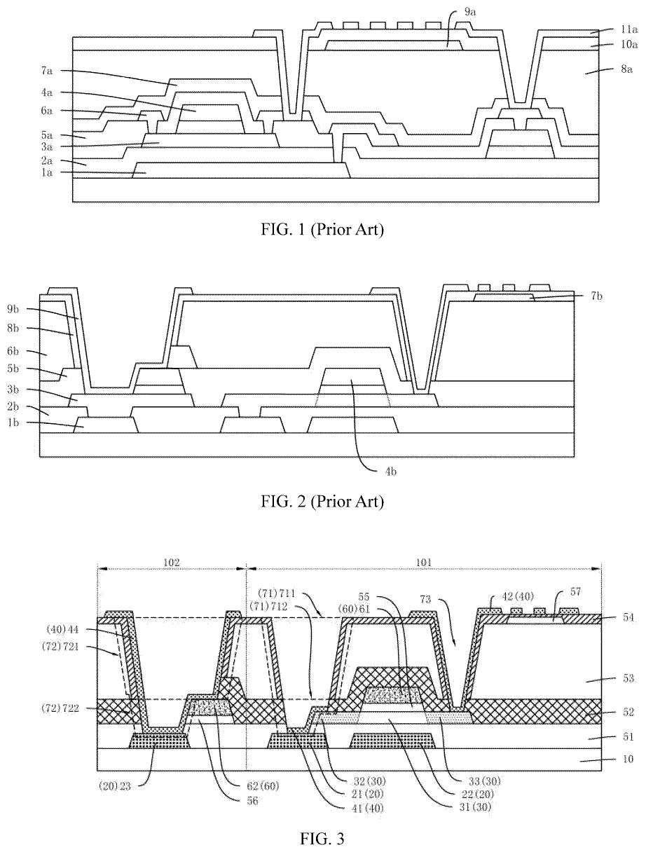

However, in the manufacturing process of the thin film transistor array substrate, it is necessary to use multiple masks to perform the photo-lithography process for multiple film layers in the thin film transistor array substrate. Specifically, in a manufacturing process of an array substrate, referring to FIG. 1, the array substrate includes a light-shielding layer 1a disposed on the substrate, a buffer layer 2a disposed on the substrate and covering the light-shielding layer 1a, an active layer 3a disposed on the buffer layer 2a, a gate insulating layer and a gate 4a disposed on the side of the active layer 3a away from the buffer layer 2a, an interlayer dielectric layer 5a disposed on the buffer layer 2a and covering the active layer 3a and the gate 4a, a source and drain layer 6a disposed on the interlayer dielectric layer 5a, a first inorganic insulating layer 7a disposed on the interlayer dielectric layer 5a and covering the source and drain layer 6a, an organic insulating layer 8a disposed on the first inorganic insulating layer 7a, a common electrode layer 9a disposed on the organic insulating layer 8a, a second inorganic insulating layer 10a disposed on the organic insulating layer 8a and covering the common electrode layer 9a, and a pixel electrode layer 11a disposed on the second inorganic insulating layer 10a. One mask is required to form the light-shielding layer 1a, one mask is required to form the active layer 3a, one mask is required to form the gate 4a and the gate insulating layer, one mask is required to form the via hole in the buffer layer 2a and the interlayer dielectric layer 5a, one mask is required to form the source and drain layer 6a, one mask is required to form the via hole in the first inorganic insulating layer 7a, one mask is required to form the via hole in the organic insulating layer 8a, one mask is required to form the common electrode layer 9a, one mask is required to form the via hole in the second inorganic insulation layer 10a, and one mask is required to form the pixel electrode layer 11a. That is, 10 mask processes are required for the structure in the display panel as shown in FIG. 1, which results in high production costs and complex processes.

Further, in a manufacturing process of another array substrate, referring to FIG. 2, the array substrate includes a data line layer 1b disposed on the substrate, a buffer layer 2b disposed on the substrate and covering the data line layer 1b, a semiconductor layer 3b disposed on the buffer layer 2b, a gate layer 4b and a gate insulating layer disposed on the semiconductor layer 3b, a first inorganic insulating layer 5b disposed on the buffer layer 2b and covering the semiconductor layer 3b and the gate layer 4b, an organic insulating layer 6b disposed on the first inorganic insulating layer 5b, a common electrode layer 7b disposed on the organic insulating layer 6b, a second inorganic insulating layer 8b disposed on the organic insulating layer 6b and covering the common electrode layer 7b, and a pixel electrode layer 9b disposed on the second inorganic insulating layer 8b. In the array substrate shown in FIG. 2, the semiconductor layer 3b is conducted to directly connect the data line layer 1b and is used as a transfer line, thereby reducing the number of masks compared to the array substrate shown in FIG. 1. Specifically, one mask is required to form the data line layer 1b, one mask is required to form the via hole in the buffer layer 2b, one mask is required to form the semiconductor layer 3b, one mask is required to form the gate layer 4b and the gate insulating layer, one mask is required to form the via hole in the organic insulating layer 6b, one mask is required to form the via hole in the first inorganic insulating layer 5b and the second inorganic insulating layer 8b, one mask is required to form the common electrode layer 7b, and one mask is required to form the pixel electrode layer 9b. That is, 8 mask processes are required for the structure in the array substrate shown in FIG. 2. Compared with the array substrate structure shown in FIG. 1, the number of masks is reduced, but the number of masks required for the array substrate structure shown in FIG. 2 is still high, resulting in high production costs and complex processes.

An embodiment of the present disclosure provides a display panel including: a substrate; a first conductive layer disposed on the substrate, wherein the first conductive layer includes a data line; an active layer disposed on a side of the first conductive layer away from the substrate, wherein the active layer includes a channel portion, and a first contacting portion and a second contacting portion connected to two opposite sides of the channel portion; and a second conductive layer disposed on a side of the active layer away from the first conductive layer; wherein the second conductive layer includes a first electrode and a second electrode, the first electrode connects the first contacting portion and the data line, the second electrode is connected to the second contacting portion, and the second electrode includes a pixel electrode or an anode.

In one embodiment of the present disclosure, the display panel further includes: a buffer layer disposed between the first conductive layer and the active layer; a first insulating layer disposed between the active layer and the second conductive layer; an organic insulating layer disposed between the first insulating layer and the second conductive layer; and a second insulating layer disposed between the organic insulating layer and the second conductive layer; wherein the display panel further includes a first opening penetrating the buffer layer, the first insulating layer, the organic insulating layer and the second insulating layer, the first electrode is located in the first opening, and part of the data line and at least part of the first contacting portion are disposed corresponding to the first opening.

In one embodiment of the present disclosure, the first opening includes a first sub-opening and a second sub-opening that are communicated with each other, the second sub-opening is located between the first sub-opening and the data line, the first sub-opening penetrates the second insulating layer and the organic insulating layer, and the second sub-opening penetrates the first insulating layer and the buffer layer; and wherein a sidewall of the first sub-opening is a surface of the second insulating layer.

In one embodiment of the present disclosure, the second insulating layer includes a first sub-portion located on the sidewall of the first sub-opening and a second sub-portion located on a surface of the organic insulating layer away from the substrate, and a thickness of the first sub-portion is less than or equal to a thickness of the second sub-portion.

In one embodiment of the present disclosure, the first contacting portion includes a first surface on a side away from the first conductive layer and a first side surface connected to the first surface, one end of the first electrode covers the first surface and the first side surface, and another end of the first electrode covers a surface of the data line away from the substrate.

In one embodiment of the present disclosure, the first conductive layer further includes a light-shielding portion disposed between the channel portion and the substrate, and the light-shielding portion is spaced apart from the data line; and wherein the data line partially overlaps the first contacting portion along a thickness direction of the display panel, the data line includes a second side surface disposed away from the light-shielding portion, the first side surface is located on a side of the first contacting portion away from the channel portion, and the second side surface is located at a side of the first side surface away from the channel portion.

In one embodiment of the present disclosure, the display panel further includes a display area and a non-display area adjacent to the display area, and at least the second electrode is disposed in the display area; wherein the first conductive layer further includes a first signal line disposed on the substrate and located in the non-display area; the display panel further includes a third conductive layer disposed between the active layer and the first insulating layer, the third conductive layer includes a gate disposed on a side of the channel portion away from the buffer layer, and a second signal line located in the non-display area; the second conductive layer further includes a transfer line located in the non-display area; and the display pane further includes a second opening penetrating the buffer layer, the first insulating layer, the organic insulating layer and the second insulating layer, at least part of the transfer line is located in the second opening, at least part of the first signal line and at least part of the second signal line are disposed corresponding to the second opening, and the transfer line connects the first signal line and the second signal line.

In one embodiment of the present disclosure, the second signal line includes a second surface on a side away from the substrate and a third side surface connected to the second surface, one end of the transfer line covers the second surface and the third side surface, and another end of the transfer line covers a surface of the first signal line away from the substrate.

In one embodiment of the present disclosure, the second opening includes a third sub-opening and a fourth sub-opening that are communicated with each other, the fourth sub-opening is located between the third sub-opening and the first signal line, the third sub-opening penetrates the second insulating layer and the organic insulating layer, and the fourth sub-opening penetrates the first insulating layer and the buffer layer; and wherein a sidewall of the third sub-opening is a surface of the second insulating layer.

In one embodiment of the present disclosure, the display panel further includes a third opening penetrating the first insulating layer, the organic insulating layer and the second insulating layer, the third opening is disposed corresponding to the second contacting portion, one end of the second electrode is located on a side of the second insulating layer away from the organic insulating layer, and another end of the second electrode passes through the third opening and is connected to the second contacting portion.

In one embodiment of the present disclosure, a thickness of the active layer is greater than or equal to 50 angstroms.

In one embodiment of the present disclosure, the display panel further includes a liquid crystal layer disposed on a side of the second conductive layer away from the substrate, and an opposite substrate disposed on a side of the liquid crystal layer away from the second conductive layer, and the second electrode is the pixel electrode; or, the display panel further includes a light-emitting functional layer disposed on a side of the second conductive layer away from the substrate, and a cathode layer disposed on a side of the light-emitting functional layer away from the second conductive layer, and the second electrode is the anode.

According to the above object of the present disclosure, an embodiment of the present disclosure further provides a manufacturing method of a display panel including: forming a first conductive layer on a substrate, wherein a data line is formed in the first conductive layer; forming an active layer on a side of the first conductive layer away from the substrate, wherein a channel portion, and a first contacting portion and a second contacting portion connected to two opposite sides of the channel portion are formed in the active layer; and forming a second conductive layer on a side of the active layer away from the first conductive layer, wherein a first electrode and a second electrode are formed in the second conductive layer, the first electrode connects the first contacting portion and the data line, the second electrode is connected to the second contacting portion, and the second electrode includes a pixel electrode or an anode.

According to the above object of the present disclosure, an embodiment of the present disclosure further provides a display device, the display device includes the display device described above, or a display device manufactured by the manufacturing method of a display panel.

In the present disclosure, the first electrode and the second electrode are disposed in the second conductive layer, the second electrode serves as the pixel electrode or the anode, and the second electrode can be directly connected to the second contacting portion of the active layer to further have the function of the source or the drain. Therefore, in the embodiments of the present disclosure, by disposing the first electrode and the second electrode in the same film layer, which is equivalent to using the same mask to form the first electrode and the pixel electrode (or the anode) and the source (or the drain), the number of masks in the manufacturing process of the display panel can be effectively reduced, and the production cost of the display panel can be reduced.

Referring to FIG. 3, an embodiment of the present disclosure provides a display panel. The display panel includes a substrate 10, a first conductive layer 20, an active layer 30 and a second conductive layer 40.

The first conductive layer 20 is disposed on the substrate 10, and the first conductive layer 20 includes the data line 21. The active layer 30 is disposed on the side of the first conductive layer 20 away from the substrate 10, and the active layer 30 includes the channel portion 31, and the first contacting portion 32 and the second contacting portion 33 connected to two opposite sides of the channel portion 31. The second conductive layer 40 is disposed on the side of the active layer 30 away from the first conductive layer 20.

Further, the second conductive layer 40 includes a first electrode 41 and a second electrode 42. The first electrode 41 connects the first contacting portion 32 and the data line 21, the second electrode 42 is connected to the second contacting portion 33, and the second electrode 42 includes a pixel electrode or an anode.

During the implementation and application process, in the embodiments of the present disclosure, the first electrode 41 and the second electrode 42 are disposed in the second conductive layer 40, the second electrode 42 serves as a pixel electrode or an anode, and the second electrode 42 can be directly connected to the second contacting portion 33 of the active layer 30 to further have the function of a source or a drain. Therefore, in the embodiments of the present disclosure, the first electrode 41 and the second electrode 42 are disposed in the same film layer, which is equivalent to using the same mask to form the first electrode. 41, the pixel electrode (or the anode) and the source (or the drain), which can effectively reduce the number of masks in the manufacturing process of the display panel and reduce the production cost of the display panel.

It should be noted that in the display panel provided by the embodiments of the present disclosure, the first electrode 41 may be one of the source and the drain, and the second electrode 42 may be multiplexed as the other one of the source and the drain. That is, in the embodiments of the present disclosure, the source and the drain can be formed in the same mask, therefore, compared with the structure shown in FIG. 2, in which the source and the drain are formed by two masks respectively, the embodiments of the present disclosure can further reduce the number of masks during the manufacturing process of the display panel, so as to reduce the production cost of the display panel.

Continuing referring to FIG. 3, in one embodiment of the present disclosure, the display panel further includes a buffer layer 51, a first insulating layer 52, an organic insulating layer 53, a second insulating layer 54, a common electrode layer 57, a gate insulating layer and a third conductive layer 60. The buffer layer 51 is disposed between the first conductive layer 20 and the active layer 30. The first insulating layer 52 is disposed between the active layer 30 and the second conductive layer 40. The organic insulating layer 53 is disposed between the first insulating layer 52 and the second conductive layer 40. The second insulating layer 54 is disposed between the organic insulating layer 53 and the second conductive layer 40, and the third conductive layer 60 and the gate insulating layer are disposed between the active layer 30 and the first insulating layer 52.

Specifically, the buffer layer 51 is disposed on the substrate 10 and covers the first conductive layer 20, the third conductive layer 60 and the gate insulating layer are disposed on the active layer 30 and the buffer layer 51. The first insulating layer 52 is disposed on the buffer layer 51 and covers the active layer 30 and the third conductive layer 60. The organic insulating layer 53 is disposed on the first insulating layer 52, the common electrode layer 57 is disposed on the organic insulating layer 53. The second insulating layer 54 is disposed on the organic insulating layer 53 and covers the common electrode layer 57, and the second conductive layer 40 is disposed on the second insulating layer 54.

In some embodiments, the display panel includes a display area 101 and a non-display area 102 adjacent to the display area 101. The first conductive layer 20 includes the data line 21 and the light-shielding portion 22 which are disposed in the display area 101, and the first signal line 23 disposed in the non-display area 102. The buffer layer 51 is configured to cover part of the data line 21, the light-shielding portion 22 and part of the first signal line 23, and the data line 21, the light-shielding portion 22 and the first signal line 23 are spaced apart.

In some embodiments, the active layer 30 is disposed on the side of the buffer layer 51 away from the light-shielding portion 22. The active layer 30 includes a channel portion 31, and a first contacting portion 32 and a second contacting portion 33 connected to two opposite sides of the channel portion 31. It can be understood that the channel portion 31 is a semiconductor material, and the first contacting portion 32 and the second contacting portion 33 may be formed of the semiconductor material after the conducting process of the semiconductor material. The light-shielding portion 22 can be located between the channel portion 31 and the substrate 11. Further and preferably, the orthographic projection of the channel portion 31 on the substrate 10 is located within the coverage of the orthographic projection of the light-shielding portion 22 on the substrate 10, so that the light-shielding portion 22 can block the light from the side of the substrate 10 and reduce the impact of light on the electrical properties of the channel portion 31.

It can be understood that it is necessary to disposed the data line 21 close to the first contacting portion 32, so as to facilitate subsequent connection between the data line 21 and the first contacting portion 32.

In some embodiments, the material of the active layer 30 may include an oxide semiconductor material, specifically, it can be a metal oxide semiconductor material. For example, the material of the active layer 30 may include at least one of indium zinc oxide (IZO), indium gallium oxide (IGO), indium gallium zinc oxide (IGZO), indium gallium tin oxide (IGTO), and indium gallium zinc tin oxide (IGZTO).

In some embodiments, the gate insulating layer includes a first gate insulating portion 55 disposed on the side of the active layer 30 away from the buffer layer 51 and a second gate insulating portion 56 disposed in the non-display area 102. The third conductive layer 60 includes a gate 61 disposed on the side of the first gate insulating portion 55 away from the active layer 30 and a second signal line 62 disposed on the side of the second gate insulating portion 56 away from the buffer layer 51. The gate insulating portion 55 is located on a surface of the channel portion 31 away from the buffer layer 51, and the gate 61 is located on a surface of the first gate insulating portion 55 away from the channel portion 31. The second signal line 62 and the second gate insulating portion 56 are disposed close to the first signal line 23, so as to facilitate the subsequent connection between the second signal line 62 and the first signal line 23.

The first insulating layer 52 covers part of the second signal line 62, part of the active layer 30, and the gate 61. The organic insulating layer 53 is located on the side of the first insulating layer 52 away from the substrate 10. The second insulating layer 54 covers the organic insulating layer 53. In some embodiments, the display panel further includes a first opening 71 penetrating the buffer layer 51, the first insulating layer 52, the organic insulating layer 53 and the second insulating layer 54, and the first opening 71 is located in the display area 101 and is disposed corresponding to the data line 21, that is, the first opening 71 is located on the side of the data line 21 away from the substrate 10. Part of the data line 21 and at least part of the first contacting portion 32 are disposed corresponding to the first opening 71, that is, the first opening 71 can expose part of the surface of the data line 21 and part of the surface of the first contacting portion 32.

In some embodiments, the second conductive layer 40 includes a first electrode 41 disposed in the display area 101, and the first electrode 41 is disposed in the first opening 71. The first electrode 41 is connected between the data line 21 and the first contacting portions 32, and is configured to transmit the data signal in the data line 21 to the active layer 30.

In some embodiments, the first contacting portion 32 includes a first surface on a side away from the first conductive layer 20 and a first side surface connected to the first surface. One end of the first electrode 41 covers the first surface and the first side surface, and the other end of the first electrode 41 covers the surface of the data line 21 away from the substrate 10. That is, compared with the structures shown in FIG. 1 and FIG. 2, in the embodiments of the present disclosure, since the first electrode 41 can cover both the first surface and the first side surface of the first contacting portion 32, so that the embodiments of the present disclosure can effectively increase the connecting area between the first contacting portion 32 and the data line 21, thereby reducing the connecting resistance among the data line 21, the first electrode 41 and the first contacting portion 32, and improving the signal transmission efficiency.

In some embodiments, the material of the second conductive layer 40 may include indium tin oxide (ITO) material. Compared with the structure shown in FIG. 2, in which conducting semiconductor materials are used to connect the data line, the first electrode 41 in the embodiments of the present disclosure has smaller resistance, which can further reduce the connecting resistance among the data line 21, the first electrode 41 and the first contacting portion 32, and improve the signal transmission efficiency.

In some embodiments, the data line 21 and the first contacting portion 32 partially overlap along the thickness direction of the display panel, which is more helpful for the first opening 71 to expose both the data line 21 and the first contacting portion 32, thereby reducing the opening area of the opening 71 and improving the space utilization of the display panel.

In some embodiments, the data line 21 includes a second side surface disposed away from the light-shielding portion 22. The first side surface is located on the side of the first contacting portion 32 away from the channel portion 31, and the second side surface is located at the side of the first side surface away from the channel portion 31. That is, a part of the data line 21 is not shielded by the first contacting portion 32 to facilitate the connection between the first electrode 41 and the data line 21.

In some embodiments, the first opening 71 includes a first sub-opening 711 and a second sub-opening 712 that are communicated with each other. The second sub-opening 712 is located between the first sub-opening 711 and the data line 21. The first sub-opening 711 penetrates the second insulating layer 54 and the organic insulating layer 53, the second sub-opening 712 penetrates the first insulating layer 52 and the buffer layer 51, and the sidewall of the first sub-opening 711 is the surface of the second insulating layer 54. In some embodiments of the present disclosure, the first opening 71 can penetrate the second insulating layer 54, the first insulating layer 52 and the buffer layer 51, and the second insulating layer 54, the first insulating layer 52 and the buffer layer 51 can all be made of inorganic insulating materials, such as silicon nitride or silicon oxide. Therefore, the opening of the second insulating layer 54, the first insulating layer 52 and the buffer layer 51 can be formed in the same mask, that is, forming the first opening 71 penetrating the second insulating layer 54, the first insulating layer 52 and the buffer layer 51, which can further reduce the number of masks and reduce the process costs.

It should be noted that since both the first insulating layer 52 and the second insulating layer 54 are made of inorganic insulating materials, water vapor blocking effect of the first insulating layer 52 and the second insulating layer 54 is better than that of the organic insulating layer 53. Therefore, in the present disclosure, the sidewall of the first sub-opening 711 is formed by the second insulating layer 54, which can effectively improve the water vapor blocking effect of the display panel, so as to reduce the possibility that the interior of the display panel will be eroded by water vapor, and increase the service life of the display panel.

In some embodiments, the second insulating layer 54 includes a first sub-portion located on the sidewall of the first sub-opening 711 and a second sub-portion located on the side of the organic insulating layer 53 away from the substrate 10, and the thickness of the first sub-portion is less than or equal to the thickness of the second sub-portion. During the dry etching process of the first opening 71, the etching gas etches downward while also etching in the horizontal direction, which may further generate etching effect on the second insulating layer 54 at the sidewall of the first sub-opening 711, and therefore, which may further cause that the thickness of the second insulating layer 54 at the sidewall of the first sub-opening 711 is smaller than the thickness of the second insulating layer 54 on the surface of the organic insulating layer 53 away from the substrate 10.

In addition, in some embodiments, the display panel further includes a second opening 72 penetrating the buffer layer 51, the first insulating layer 52, the organic insulating layer 53 and the second insulating layer 54, at least a part of the first signal line 23 and at least a part of the second signal line 62 are disposed corresponding to the second opening 72. The second opening 72 is located in the non-display area 102 and on the side of the first signal line 23 away from the substrate 10. The second opening 72 can expose part of the surface of the first signal line 23 and part of the surface of the second signal line 62, and the second signal line 62 is disposed close to the first signal line 23, which are helpful for the second opening 72 to expose both the first signal line 23 and the second signal line 62, which is conducive to reducing the aperture of the second opening 72 and improving the space utilization of the display panel.

Further, the second conductive layer 40 further includes a transfer line 44 disposed in the non-display area 102 and at least partially located in the second opening 72, and the transfer line 44 is connected between the first signal line 23 and the second signal line 62. A part of the transfer line 44 may be located in the second opening 72 and connected between the first signal line 23 and the second signal line 62, and the other part may extend outside the second opening 72 and be located on the surface of the second insulating layer 54 away from the substrate 10.

In one embodiment, the second signal line 62 includes a second surface on a side away from the substrate 10 and a third side surface connected to the second surface. One end of the transfer line 44 covers the second surface and the third side surface, and the other end of the transfer line 44 covers the surface of the first signal line 23 away from the substrate 10. That is, compared with the structures shown in FIG. 1 and FIG. 2, in the embodiments of the present disclosure, since the transfer line 44 can cover both the first surface and the first side surface of the second signal line 62, the embodiments of the present disclosure can effectively increase the connecting area between the second signal line 62 and the first signal line 23, so as to reduce the connecting resistance among the transfer line 44, the second signal line 62 and the first signal line 23, and improve the signal transmission efficiency. Furthermore, since the material of the second conductive layer 40 may include ITO material, compared to the structure shown in FIG. 2 in which conducting semiconductor materials are used for transfer, the resistance of the transfer line 44 in the embodiments of the present disclosure is smaller, which can further reduce the connecting resistance among the transfer line 44, the second signal line 62 and the first signal line 23, and improve the signal transmission efficiency.

In some embodiments, the second opening 72 includes a third sub-opening 721 and a fourth sub-opening 722 that are communicated with each other. The fourth sub-opening 722 is located between the third sub-opening 721 and the first signal line 23. The third sub-opening 721 penetrates the second insulating layer 54 and the organic insulating layer 53, the fourth sub-opening 722 penetrates the first insulating layer 52 and the buffer layer 51; and the sidewall of the third sub-opening 721 is the surface of the second insulating layer 54. In some embodiments of the present disclosure, the second opening 72 can penetrate the second insulating layer 54, the first insulating layer 52 and the buffer layer 51, and the second insulating layer 54, the first insulating layer 52 and the buffer layer 51 can all be made of inorganic insulating materials, such as silicon nitride or silicon oxide. Therefore, the opening of the second insulating layer 54, the first insulating layer 52 and the buffer layer 51 can be formed in the same mask, that is, the first opening 71 and the second opening 72 penetrating the second insulating layer 54, the first insulating layer 52 and the buffer layer 51 can be formed in the same mask, which can further reduce the number of masks and reduce the process costs.

It should be noted that since both the first insulating layer 52 and the second insulating layer 54 are made of inorganic insulating materials, water vapor blocking effect of the first insulating layer 52 and the second insulating layer 54 is better than that of the organic insulating layer 53. Therefore, in the present disclosure, the sidewall of the third sub-opening 721 is formed by the second insulating layer 54, which can effectively improve the water vapor blocking effect of the display panel, so as to reduce the possibility that the interior of the display panel will be eroded by water vapor, and increase the service life of the display panel.

In some embodiments, the thickness of the second insulating layer 54 located on the sidewall of the third sub-opening 721 is less than or equal to the thickness of the second insulating layer 54 on the surface of the organic insulating layer 53 away from the substrate 10. During the dry etching process of the second opening 72, while the etching gas etches downward, it also etches in the horizontal direction, which may generate an etching effect on the second insulating layer 54 at the sidewall of the third sub-opening 721, and therefore, which may further cause that the thickness of the second insulating layer 54 covering the sidewall of the third sub-opening 721 is smaller than the thickness of the second insulating layer 54 on the surface of the organic insulating layer 53 away from the substrate 10.

In some embodiments, the display panel further includes a third opening 73 penetrating the first insulating layer 52, the organic insulating layer 53 and the second insulating layer 54. The third opening 73 is disposed corresponding to the second contacting portion 33, that is, the third opening 73 may be located on the side of the second contacting portion 33 away from the substrate 10 and is located in the display area 101. One end of the second electrode 42 is located on the side of the second insulating layer 54 away from the organic insulating layer 53, and the other end of the second electrode 42 passes through the third opening 73 and is connected to the second contacting portion 33, that is, the second electrode 42 may have the function of a source or a drain.

It should be noted that in the embodiments of the present disclosure, the first opening 71, the second opening 72 and the third opening 73 are all formed in the same mask. Therefore, during the dry etching process of the first opening 71, the second opening 72 and the third opening 73, the etching capacity of the etching gas is the same. Each of the first opening 71 and the second opening 72 penetrates the second insulating layer 54, the organic insulating layer 53, the first insulating layer 52 and the buffer layer 51. The depth of the third opening 73 is less than the depth of the first opening 71 and the depth of the second opening 72, and the third opening 73 penetrates the second insulating layer 54, the organic insulating layer 53 and the first insulating layer 52. In order to prevent the second contacting portion 33 from being etched through, it is necessary that the thickness of the second contacting portion 33 is greater than or equal to 50 angstroms, that is, it is necessary that the thickness of the active layer 30 is greater than or equal to 50 angstroms, so that the etching of the third opening 73 can stop at the second contacting portion 33 to avoid the second contacting portion 33 being etched through, and which may cause that the active layer 30 cannot be connected to the second electrode 42.

In some embodiments, since the second contacting portion 33 may be partially etched during the etching process, the average thickness of the second contacting portion 33 may be less than or equal to the average thickness of the first contacting portion 32.

In some embodiments, the display panel may further include a liquid crystal layer disposed on the side of the second conductive layer 40 away from the substrate 10, and an opposite substrate disposed on the side of the liquid crystal layer away from the second conductive layer 40. Structures such as a color filter layer can be disposed on the opposite substrate, that is, in some embodiments, the display panel may be a liquid crystal display panel.

The second electrode 42 is the pixel electrode disposed in the display area 101, and the second electrode 42 is electrically connected to the active layer 30, the first electrode 41 and the data line 21, so as to obtain the data signals in the data line 21. The second electrode 42 can form an electric field with the common electrode layer 57 to control the deflection of liquid crystal molecules in the liquid crystal layer.

Based on the above, in the embodiments of the present disclosure, the first electrode 41 and the second electrode 42 are disposed in the second conductive layer 40, the second electrode 42 serves as the pixel electrode or an anode, and the second electrode 42 can be directly connected to the second contacting portion 33 of the active layer 30 to further have the function of a source or a drain. Therefore, in the embodiments of the present disclosure, by disposing the first electrode 41 and the second electrode 42 in the same film layer, which is equivalent to using the same mask to form the first electrode 41 and the pixel electrode (or the anode) and the source (or the drain), the number of masks in the manufacturing process of the display panel can be effectively reduced, and the production cost of the display panel can be reduced. In addition, during the formation of the first opening 71, the second opening 72 and the third opening 73, the buffer layer 51 may be formed in the same mask as the first insulating layer 52 and the second insulating layer 54, which can further reduce the number of masks in the manufacturing process of the display panel and reduce the production cost of the display panel.

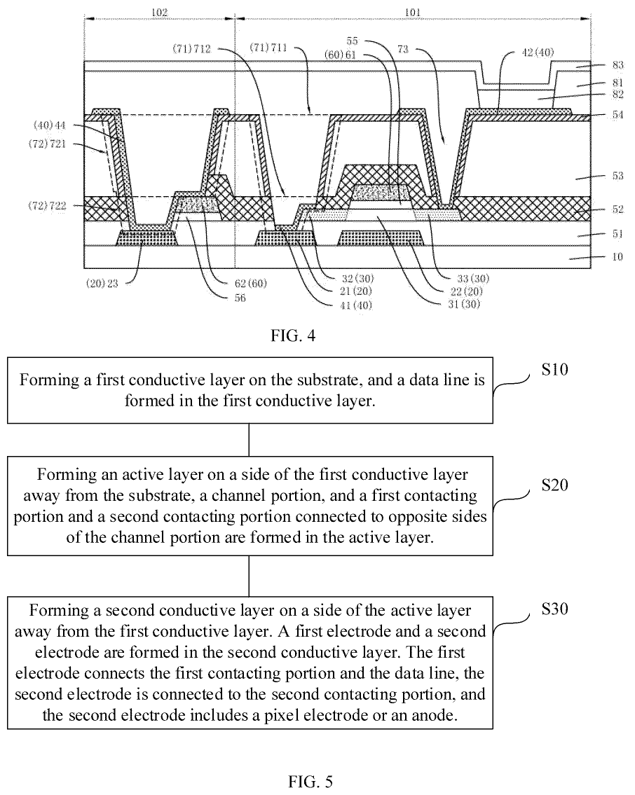

Referring to FIG. 4, in another embodiment of the present disclosure, the difference between this embodiment and the embodiment shown in FIG. 3 is that: the display panel provided in some embodiments is an organic light-emitting diode display panel.

Specifically, the display panel further includes a pixel defining layer 81 and a light-emitting functional layer 82 disposed on the side of the second conductive layer 40 away from the substrate 10, and a cathode layer 83 disposed on the side of each of the pixel defining layer 81 and the light-emitting functional layer 82 away from the second conductive layer 40, and the second electrode 42 may be an anode.

The pixel defining layer 81 is disposed on the side of the second conductive layer 40 away from the substrate 10 and fills the first opening 71, the second opening 72 and the third opening 73. A plurality of pixel openings are formed in the pixel defining layer 81, the pixel opening can expose the surface of the second electrode 42. The light-emitting functional layer 82 is at least disposed in the pixel openings and is located on the surface of the second electrode 42 away from the second insulating layer 54, the cathode layer 83 covers the surfaces of the pixel defining layer 81 and of the light-emitting function layer 82 away from the second electrode 42.

Based on the above, in the embodiments of the present disclosure, the first electrode 41 and the second electrode 42 are disposed in the second conductive layer 40, the second electrode 42 serves as the pixel electrode or an anode, and the second electrode 42 can be directly connected to the second contacting portion 33 of the active layer 30 to further have the function of a source or a drain. Therefore, in the embodiments of the present disclosure, by disposing the first electrode 41 and the second electrode 42 in the same film layer, which is equivalent to using the same mask to form the first electrode 41 and the pixel electrode (or the anode) and the source (or the drain), the number of masks in the manufacturing process of the display panel can be effectively reduced, and the production cost of the display panel can be reduced. In addition, during the formation of the first opening 71, the second opening 72 and the third opening 73, the buffer layer 51 may be formed in the same mask as the first insulating layer 52 and the second insulating layer 54, which can further reduce the number of masks in the manufacturing process of the display panel and reduce the production cost of the display panel.

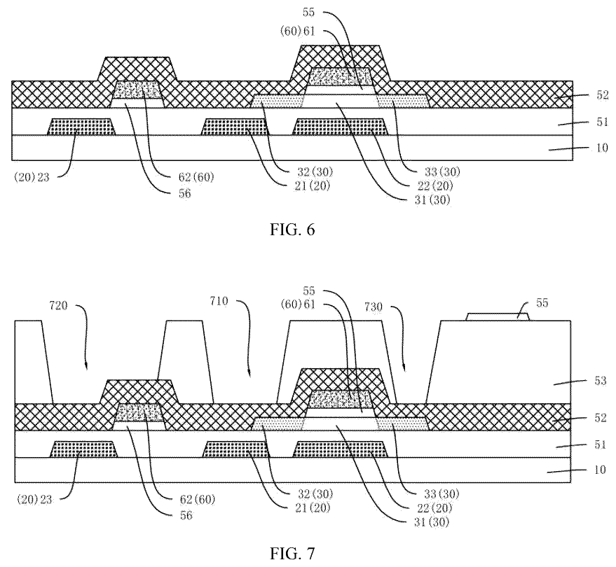

In addition, referring to FIG. 3, FIG. 5, and FIG. 6 to FIG. 9, an embodiment of the present disclosure further provides a manufacturing method of the display panel in any one of the embodiments described above, and the manufacturing method includes following operations.

S10, forming a first conductive layer on a substrate, and a data line is formed in the first conductive layer.

S20, forming an active layer on a side of the first conductive layer away from the substrate, a channel portion, and a first contacting portion and a second contacting portion connected to two opposite sides of the channel portion are formed in the active layer.

S30, forming a second conductive layer on a side of the active layer away from the first conductive layer. A first electrode and a second electrode are formed in the second conductive layer. The first electrode connects the first contacting portion and the data line, the second electrode is connected to the second contacting portion, and the second electrode includes a pixel electrode or an anode.

Specifically, in step S10, a patterned first conductive layer 20 is formed on the substrate 10 by using a first mask process, and a data line 21 and a light-shielding portion 22 that are located in the display area 101, and a first signal line 23 located in the non-display area 102 are formed in the first conductive layer 20.

Next, a buffer layer 51 covering the data line 21, the light-shielding portion 22, and the first signal line 23 is formed on the substrate 10. The material of the buffer layer 51 may include an inorganic insulating material, such as silicon nitride or silicon oxide.

In step S20, the active layer 30 is formed on the side of the buffer layer 51 away from the first conductive layer 20 by using a second mask process, and the active layer 30 is formed on the side of the light-shielding portion 22 away from the substrate 10. The active layer 30 includes a channel portion 31, and a first contacting portion 32 and a second contacting portion 33 connected to two opposite sides of the channel portion 31. The light-shielding portion 22 is located between the channel portion 31 and the substrate 10.

In some embodiments, the material of the active layer 30 may include an oxide semiconductor material, specifically, a metal oxide semiconductor material. For example, the material of the active layer 30 may include at least one of indium zinc oxide (IZO), indium gallium oxide (IGO), indium gallium zinc oxide (IGZO), indium gallium tin oxide (IGTO) and indium gallium zinc tin oxide (IGZTO).

Next, a patterned gate insulating layer and a third conductive layer 60 are formed on the active layer 30 and the buffer layer 51 by using a third mask process. The gate insulating layer includes a first gate insulating portion 55 formed on the side of the channel portion 31 away from the light-shielding portion 22, and a second gate insulating portion 56 located in the non-display area 102 and disposed close to the first signal line 23. The third conductive layer 60 includes a gate 61 formed on the side of the first gate insulating portion 55 away from the channel portion 31, and the second signal line 62 located on the side of the second gate insulating portion 56 away from the buffer layer 51.

Then, the first insulating layer 52 covering the active layer 30 and the third conductive layer 60 is formed on the buffer layer 51, as shown in FIG. 6. The material of the first insulating layer 52 may include inorganic insulating materials, such as silicon nitride or silicon oxide.

Next, a patterned organic insulating layer 53 is formed on the first insulating layer 52 by using a fourth mask process. A first middle hole 710 corresponding to the data line 21 and the first contacting portion 32, a second middle hole 720 corresponding to the first signal line 23 and the second signal line 62, and a third middle hole 730 corresponding to the second contacting portion 33 are formed in the organic insulating layer 53, as shown in FIG. 7. The material of the organic insulating layer 53 includes organic insulating materials, such as acrylic or polyimide.

Then, a patterned common electrode layer 57 is formed on the side of the organic insulating layer 53 away from the first insulating layer 52 by using a fifth mask process.

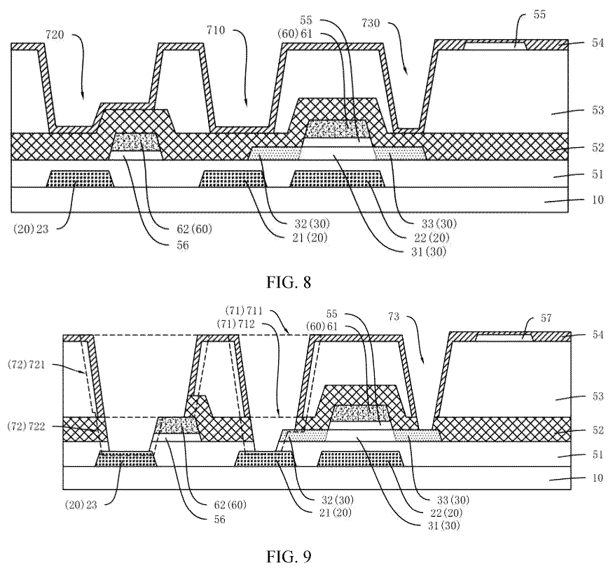

A second insulating layer 54 covering the common electrode layer 57 is formed on the side of the organic insulating layer 53 away from the first insulating layer 52. The second insulating layer 54 further covers the sidewall and bottom portion of each of the first middle hole 710, the second middle hole 720 and the third middle hole 710, as shown in FIG. 8. The material of the second insulating layer 54 may include inorganic insulating materials, such as silicon nitride or silicon oxide.

Since the second insulating layer 54, the first insulating layer 52 and the buffer layer 51 are all made of inorganic materials, such as silicon nitride material or silicon oxide material, the second insulating layer 54, the first insulating layer 54 and the first buffer layer 51 can be etched by using a sixth mask process, a first opening 71 corresponding to the first middle hole 710 is formed, a second opening 72 corresponding to the second middle hole 720 is formed, and a third opening 73 corresponding to the third middle hole 730 is formed. The first opening 71 penetrates the second insulating layer 54, the organic insulating layer 53, the first insulating layer 52 and the buffer layer 51, and part of the data line 21 and at least part of the first contacting portion 32 are located in the first opening 71. The second opening 72 penetrates the second insulating layer 54, the organic insulating layer 53, the first insulating layer 52 and the buffer layer 51. Part of the first signal line 23 and part of the second signal line 62 are located in the second opening 72. The third opening 73 penetrates the second insulating layer 54, the organic insulating layer 53 and the first insulating layer 52, and part of the second contacting portion 33 is located in the third opening 73, as shown in FIG. 9.

A conductive material layer is formed on the side of the second insulating layer 54 away from the organic insulating layer 53, and the conductive material layer is patterned by using a seventh mask process to form the second conductive layer 40.

The second conductive layer 40 includes a first electrode 41 located in the first opening 71, a transfer line 44 located at least in the second opening 72, and a second electrode 42 located at least in the third opening 73.

Further, the first electrode 41 is connected between the data line 21 and the first contacting portion 32 in the first opening 71. One end of the second electrode 42 is connected to the second contacting portion 33 in the third opening 73, and the other end of the second electrode 42 is located on the surface of the second insulating layer 54 away from the organic insulating layer 53. The transfer line 44 is connected between the first signal line 23 and the second signal line 62 in the second opening 72, as shown in FIG. 3.

In summary, in the embodiments of the present disclosure, the first electrode 41 and the second electrode 42 are disposed in the second conductive layer 40, the second electrode 42 serves as the pixel electrode or an anode, and the second electrode 42 can be directly connected to the second contacting portion 33 of the active layer 30 to further have the function of a source or a drain. Therefore, in the embodiments of the present disclosure, the first electrode 41 and the second electrode 42 are disposed in the same film layer, which is equivalent to using the same mask to form the first electrode 41 and the pixel electrode (or the anode) and the source (or the drain). In addition, during the formation of the first opening 71, the second opening 72 and the third opening 73, the buffer layer 51 may be formed in the same mask as the first insulating layer 52 and the second insulating layer 54, so that in the embodiments of the present disclosure, the display panel shown in FIG. 3 can be formed by only using seven mask processes, compared with the structures shown in FIG. 1 and FIG. 2, which can effectively reduce the number of masks in the manufacturing process of the display panel and reduce the production cost of the display panel.

In addition, an embodiment of the present disclosure further provides a display device, the display device includes the display panel in any of the embodiments described above, or the display panel manufactured by using the manufacturing method of the display panel in any of the embodiments described above.

In some embodiments, the display device may be a liquid crystal display or an organic light-emitting diode display.

It can be understood that since the display device includes the display panel in any one of the embodiments described above, the display device has the same beneficial effects as the display panel in any one of the embodiments described above, which will not be described again herein.

In the description of the present disclosure, the terms “first” and “second” are used for descriptive purposes only, and cannot be understood as indicating or implying relative importance or implicitly indicating the number of indicated technical features. Therefore, the features defined as the “first” and the “second” may explicitly or implicitly include one or more features. In the description of the present disclosure, “a plurality of” means two or more than two, unless otherwise explicitly and specifically limited.

In the embodiments described above, each embodiment is described with its own emphasis. For parts that are not described in detail in a certain embodiment, reference can be made to the relevant descriptions of other embodiments.

The embodiments, implementations and related technical features of the present disclosure can be combined and replaced with each other without conflict.

What described above are only preferred embodiments of the present disclosure and are not intended to limit the present disclosure in any form. Any simple modification, equivalent change and embellishment to the above embodiments based on the technical essence of the present disclosure without departing from the content of the technical solution of the present disclosure still fall within the scope of the technical solution of the present disclosure.

What is claimed is:

1. A display panel comprising:
a substrate;
a first conductive layer disposed on the substrate, wherein the first conductive layer comprises a data line;
an active layer disposed on a side of the first conductive layer away from the substrate, wherein the active layer comprises a channel portion, and a first contacting portion and a second contacting portion connected to two opposite sides of the channel portion; and
a second conductive layer disposed on a side of the active layer away from the first conductive layer;
wherein the second conductive layer comprises a first electrode and a second electrode, the first electrode connects the first contacting portion and the data line, the second electrode is connected to the second contacting portion, and the second electrode comprises a pixel electrode or an anode.

2. The display panel according to claim 1, wherein the display panel further comprises:
a buffer layer disposed between the first conductive layer and the active layer;
a first insulating layer disposed between the active layer and the second conductive layer;
an organic insulating layer disposed between the first insulating layer and the second conductive layer; and
a second insulating layer disposed between the organic insulating layer and the second conductive layer;
wherein the display panel further comprises a first opening penetrating the buffer layer, the first insulating layer, the organic insulating layer and the second insulating layer, the first electrode is located in the first opening, and part of the data line and at least part of the first contacting portion are disposed corresponding to the first opening.

3. The display panel according to claim 2, wherein the first opening comprises a first sub-opening and a second sub-opening that are communicated with each other, the second sub-opening is located between the first sub-opening and the data line, the first sub-opening penetrates the second insulating layer and the organic insulating layer, and the second sub-opening penetrates the first insulating layer and the buffer layer; and
wherein a sidewall of the first sub-opening is a surface of the second insulating layer.

4. The display panel according to claim 3, wherein the second insulating layer comprises a first sub-portion located on the sidewall of the first sub-opening and a second sub-portion located on a surface of the organic insulating layer away from the substrate, and a thickness of the first sub-portion is less than or equal to a thickness of the second sub-portion.

5. The display panel according to claim 2, wherein the display panel further comprises a display area and a non-display area adjacent to the display area, and at least the second electrode is disposed in the display area;
wherein the first conductive layer further comprises a first signal line disposed on the substrate and located in the non-display area;
the display panel further comprises a third conductive layer disposed between the active layer and the first insulating layer, the third conductive layer comprises a gate disposed on a side of the channel portion away from the buffer layer, and a second signal line located in the non-display area;
the second conductive layer further comprises a transfer line located in the non-display area; and
the display pane further comprises a second opening penetrating the buffer layer, the first insulating layer, the organic insulating layer and the second insulating layer, at least part of the transfer line is located in the second opening, at least part of the first signal line and at least part of the second signal line are disposed corresponding to the second opening, and the transfer line connects the first signal line and the second signal line.

6. The display panel according to claim 5, wherein the second signal line comprises a second surface on a side away from the substrate and a third side surface connected to the second surface, one end of the transfer line covers the second surface and the third side surface, and another end of the transfer line covers a surface of the first signal line away from the substrate.

7. The display panel according to claim 5, wherein the second opening comprises a third sub-opening and a fourth sub-opening that are communicated with each other, the fourth sub-opening is located between the third sub-opening and the first signal line, the third sub-opening penetrates the second insulating layer and the organic insulating layer, and the fourth sub-opening penetrates the first insulating layer and the buffer layer; and
wherein a sidewall of the third sub-opening is a surface of the second insulating layer.

8. The display panel according to claim 2, wherein the display panel further comprises a third opening penetrating the first insulating layer, the organic insulating layer and the second insulating layer, the third opening is disposed corresponding to the second contacting portion, one end of the second electrode is located on a side of the second insulating layer away from the organic insulating layer, and another end of the second electrode passes through the third opening and is connected to the second contacting portion.

9. The display panel according to claim 8, wherein a thickness of the active layer is greater than or equal to 50 angstroms.

10. The display panel according to claim 1, wherein a thickness of the active layer is greater than or equal to 50 angstroms.

11. The display panel according to claim 1, wherein the first contacting portion comprises a first surface on a side away from the first conductive layer and a first side surface connected to the first surface, one end of the first electrode covers the first surface and the first side surface, and another end of the first electrode covers a surface of the data line away from the substrate.

12. The display panel according to claim 11, wherein the first conductive layer further comprises a light-shielding portion disposed between the channel portion and the substrate, and the light-shielding portion is spaced apart from the data line; and
wherein the data line partially overlaps the first contacting portion along a thickness direction of the display panel, the data line comprises a second side surface disposed away from the light-shielding portion, the first side surface is located on a side of the first contacting portion away from the channel portion, and the second side surface is located at a side of the first side surface away from the channel portion.

13. The display panel according to claim 1, wherein the display panel further comprises a liquid crystal layer disposed on a side of the second conductive layer away from the substrate, and an opposite substrate disposed on a side of the liquid crystal layer away from the second conductive layer, and the second electrode is the pixel electrode;
or, the display panel further comprises a light-emitting functional layer disposed on a side of the second conductive layer away from the substrate, and a cathode layer disposed on a side of the light-emitting functional layer away from the second conductive layer, and the second electrode is the anode.

14. A manufacturing method of a display panel comprising:
forming a first conductive layer on a substrate, wherein a data line is formed in the first conductive layer;
forming an active layer on a side of the first conductive layer away from the substrate, wherein a channel portion, and a first contacting portion and a second contacting portion connected to two opposite sides of the channel portion are formed in the active layer; and
forming a second conductive layer on a side of the active layer away from the first conductive layer, wherein a first electrode and a second electrode are formed in the second conductive layer, the first electrode connects the first contacting portion and the data line, the second electrode is connected to the second contacting portion, and the second electrode comprises a pixel electrode or an anode.

15. A display device, wherein the display device comprises a display panel manufactured by the manufacturing method of a display panel according to claim 14.

16. A display device, wherein the display device comprises a display panel, wherein the display panel comprises:
a substrate;
a first conductive layer disposed on the substrate, wherein the first conductive layer comprises a data line;
an active layer disposed on a side of the first conductive layer away from the substrate, wherein the active layer comprises a channel portion, and a first contacting portion and a second contacting portion connected to two opposite sides of the channel portion; and
a second conductive layer disposed on a side of the active layer away from the first conductive layer;
wherein the second conductive layer comprises a first electrode and a second electrode, the first electrode connects the first contacting portion and the data line, the second electrode is connected to the second contacting portion, and the second electrode comprises a pixel electrode or an anode.

17. The display device according to claim 16, wherein the display panel further comprises:
a buffer layer disposed between the first conductive layer and the active layer;
a first insulating layer disposed between the active layer and the second conductive layer;
an organic insulating layer disposed between the first insulating layer and the second conductive layer; and
a second insulating layer disposed between the organic insulating layer and the second conductive layer;
wherein the display panel further comprises a first opening penetrating the buffer layer, the first insulating layer, the organic insulating layer and the second insulating layer, the first electrode is located in the first opening, and part of the data line and at least part of the first contacting portion are disposed corresponding to the first opening.

18. The display device according to claim 17, wherein the first opening comprises a first sub-opening and a second sub-opening that are communicated with each other, the second sub-opening is located between the first sub-opening and the data line, the first sub-opening penetrates the second insulating layer and the organic insulating layer, and the second sub-opening penetrates the first insulating layer and the buffer layer; and
wherein a sidewall of the first sub-opening is a surface of the second insulating layer.

19. The display device according to claim 18, wherein the second insulating layer comprises a first sub-portion located on the sidewall of the first sub-opening and a second sub-portion located on a surface of the organic insulating layer away from the substrate, and a thickness of the first sub-portion is less than or equal to a thickness of the second sub-portion.

20. The display device according to claim 16, wherein the first contacting portion comprises a first surface on a side away from the first conductive layer and a first side surface connected to the first surface, one end of the first electrode covers the first surface and the first side surface, and another end of the first electrode covers a surface of the data line away from the substrate.
